(19) United States
(12) Patent Application Publication
(10) Pub. No.: US 2016/0219732 A1
(43) Pub. Date: Jul. 28, 2016

(54) CURVED DISPLAY DEVICE

(71) Applicant: SAMSUNG DISPLAY CO., LTD., Yongin-City (KR)

(72) Inventors: YOUNG JE CHO, Asan-si (KR); Yu Jin Lee, Suwon-si (KR); Min Chul Song, Cheonan-si (KR); Yeon Mun Jeon, Hwaseong-si (KR)

(21) Appl. No.: 14/717,095

(22) Filed: May 20, 2015

(30) Foreign Application Priority Data
Jan. 26, 2015 (KR) 10-2015-0011913

(51) Int. Cl. H05K 5/02; H05K 5/00

(52) U.S. Cl. CPC H05K 5/0217; H05K 5/0017; H05K 5/0004

(57) ABSTRACT

A curved display device includes a curved display panel including a first substrate and a second substrate facing the first substrate, the first substrate including a display area for displaying an image and a non-display area, a sealing member interposed between the first substrate and the second substrate and surrounding the display area, and a reinforcement member arranged on an outside of the sealing member, wherein the curved display panel includes a first side surface including a curved side, a second side surface including a curved side and facing the first side surface, a third side surface and a fourth side surface connecting the first side surface and the second side surface, the third side surface and the fourth side surface facing each other, and wherein the reinforcement member is attached to at least one of the first side surface and the second side surface.

### CROSS-REFERENCE TO RELATED APPLICATION

This application claims priority under 35 U.S.C. §119 to Korean Patent Application No. 10-2015-0011913, filed on Jan. 26, 2015, in the Korean Intellectual Property Office, the disclosure of which is incorporated by reference herein in its entirety.

### TECHNICAL FIELD

Exemplary embodiments of the present invention relate to a curved display device.

### DISCUSSION OF THE RELATED ART

A liquid crystal display (LCD) is one type of a display device. The LCD is a device that displays an image by changing molecular arrangements of liquid crystals in respective pixels by applying a power to upper and lower electrodes formed on two glass substrates. The liquid crystals are injected between the glass substrates.

Unlike a cathode ray tube (CRT) display device or a plasma display panel (PDP) display device, the LCD device is not self-luminous. Thus, the LCD device is unusable in a place where there is no light. Accordingly, to use the LCD device in a dark place, the LCD device includes a backlight unit that irradiates light to a display panel to displaying an image with uniform light.

A display panel may be produced by bonding upper and lower substrates. Elements for displaying an image are formed, using a sealant, to form a mother panel, and cutting the mother panel in the unit of a cell (e.g., one cell may correspond to one display device).

However, cracks may occur on cut surfaces of the upper and lower substrates during the cutting process described above. When an impact or stress (e.g., stress due to a process of bending upper and lower flat substrates to implement a curved display device) is applied to the upper substrate or the lower substrate, such cracks may propagate to the inside of the upper substrate or the lower substrate and may damage the upper substrate or the lower substrate. Thus, long-term reliability of the display panel being used may decrease.

### SUMMARY

Exemplary embodiments of the present invention provide a display device which can improve long-term reliability of a display panel being used.

In an exemplary embodiment of the present invention, a curved display device includes a curved display panel including a first substrate and a second substrate facing the first substrate, wherein the first substrate includes a display area for displaying an image and a non-display area, a sealing member interposed between the first substrate and the second substrate, wherein the sealing member surrounds the display area, and a reinforcement member arranged on an outside of the sealing member, wherein the curved display panel includes a first side surface including a curved side, a second side surface including a curved side and facing the first side surface, a third side surface, and a fourth side surface, wherein the third side surface connects the first side surface and the second side surface, and the fourth side surface connects the first side surface and the second side surface, wherein the third side surface and the fourth side surface face each other, and wherein the reinforcement member is attached to at least one of the first side surface and the second side surface.

In an exemplary embodiment of the present invention, the reinforcement member may include a curved side.

In an exemplary embodiment of the present invention, a first side surface of the first substrate that corresponds to the first side surface of the curved display panel may be arranged on the same plane as a first side surface of the second substrate that corresponds to the first side surface of the curved display panel, and the reinforcement member may comprise a first reinforcement member, the first reinforcement member including a first portion arranged on the first side surface of the first substrate, a second portion arranged on the first side surface of the second substrate, and a third portion connecting the first portion and the second portion to each other.

In an exemplary embodiment of the present invention, the first portion, the second portion, and the third portion of the first reinforcement member may form a continuous structure.

In an exemplary embodiment of the present invention, a second side surface of the first substrate that corresponds to the second side surface of the curved display panel and a second side surface of the second substrate that corresponds to the second side surface of the curved display panel may be arranged on planes that are different from each other, and the reinforcement member may further comprise a second reinforcement member, the second reinforcement member including a first portion arranged on the second side surface of the first substrate and a second portion arranged on the second side surface of the second substrate.

In an exemplary embodiment of the present invention, the first portion and the second portion of the second reinforcement member may be spaced apart from each other.

In an exemplary embodiment of the present invention, the reinforcement member may be attached to at least one of the third side surface and the fourth side surface.

In an exemplary embodiment of the present invention, a third side surface of the first substrate that corresponds to the third side surface of the curved display panel may be arranged on the same plane as a third side surface of the second substrate that corresponds to the third side surface of the curved display panel, and the reinforcement member may further include a third reinforcement member, the third reinforcement member including a first portion arranged on the third side surface of the first substrate, a second portion arranged on the third side surface of the second substrate, and a third portion connecting the first portion and the second portion to each other.

In an exemplary embodiment of the present invention, a fourth side surface of the first substrate that corresponds to the fourth side surface of the curved display panel may be arranged on the same plane as a fourth side surface of the second substrate that corresponds to the fourth side surface of the curved display panel, and the reinforcement member may further include a fourth reinforcement member, the fourth reinforcement member including a first portion arranged on the fourth side surface of the first substrate, a second portion arranged on the fourth side surface of the second substrate, and a third portion connecting the first portion and the second portion to each other.

In an exemplary embodiment of the present invention, the reinforcement member may have a connected structure.

In an exemplary embodiment of the present invention, the curved display panel may include a first curved surface and a second curved surface, wherein the first and second curved surfaces connect the first side surface, the second side surface, the third side surface and the fourth side surface, wherein the first and second curved surfaces are parallel to each other, wherein the reinforcement member may include an extension portion, and wherein the extension portion extends from at least one of the first side surface and the second side surface to edges of the first curved surface and the second curved surface.

In an exemplary embodiment of the present invention, the reinforcement member may include the same material as the sealing member.

In an exemplary embodiment of the present invention, the reinforcement member may be formed of a material that is different from a material of the sealing member.

In an exemplary embodiment of the present invention, the reinforcement member may include frit.

In an exemplary embodiment of the present invention, the reinforcement member may fill at least one crack on at least one of the first side surface and the second side surface of the curved display panel.

In an exemplary embodiment of the present invention, a curved display device includes a curved display panel including a first substrate and a second substrate facing the first substrate, wherein the first substrate includes a display area for displaying an image and a non-display area, a sealing member interposed between the first substrate and the second substrate, wherein the sealing member surrounds the display area, and a reinforcement member arranged on an outside of the sealing member, wherein the reinforcement member includes a first portion arranged on a first side surface of the first substrate, a second portion arranged on a first side surface of the second substrate, wherein the first side surface of the second substrate corresponds to the first side surface of the first substrate, and a third portion connecting the first portion and the second portion to each other.

In an exemplary embodiment of the present invention, the first portion, the second portion, and the third portion may form a continuous structure.

In an exemplary embodiment of the present invention, the first side surface of the first substrate and the first side surface of the second substrate may be arranged on the same plane.

In an exemplary embodiment of the present invention, the first side surface of the first substrate and the first side surface of the second substrate may include curved sides or straight sides.

In an exemplary embodiment of the present invention, the reinforcement member may include the same material as the sealing member or a material that is different from a material of the sealing member.

In an exemplary embodiment of the present invention, the reinforcement member may include frit.

In an exemplary embodiment of the present invention, at least one of the first portion of the reinforcement member and the second portion of the reinforcement member may fill at least one crack on at least one of the first side surface of the first substrate and the first side surface of the second substrate.

In an exemplary embodiment of the present invention, a method for creating a curved display device includes receiving a first mother substrate and a second mother substrate, wherein the first mother substrate includes a display area and a non-display area, spreading a sealing member on the second mother substrate, providing elements for displaying an image on the first mother substrate and providing elements for displaying an image on the second mother substrate, bonding the first and the second mother substrates using the sealing member, the first and the second mother substrates facing each other, cutting the bonded first and second mother substrates to form a display panel, bending the display panel to form a curved display panel, the curved display panel comprising a first curved side surface, a second curved side surface, a third straight side surface, and a fourth straight side surface, and disposing a reinforcement member on the first curved side surface, the second curved side surface, the third straight side surface, or the fourth straight side surface of the display panel.

In an exemplary embodiment of the present invention, the reinforcement member may include a curved side surface.

In an exemplary embodiment of the present invention, the reinforcement member may fill at least one crack on the first curved side surface, the second curved side surface, the third straight side surface, or the fourth straight side surface of the display panel.

### BRIEF DESCRIPTION OF THE DRAWINGS

The above and other objects, and features of the present invention will become more apparent by describing in detail exemplary embodiments thereof in conjunction with the accompanying drawings, in which:

FIG. 1 is a perspective view of a curved display device in an assembled state according to an exemplary embodiment of the present invention;

FIG. 2 is an exploded perspective view of the curved display device of FIG. 1, according to an exemplary embodiment of the present invention;

FIG. 3 is a plan view illustrating pixels of the curved display device of FIG. 1, according to an exemplary embodiment of the present invention;

FIG. 4 is a perspective view of a curved display panel and a sealing member in a separated state of the curved display device of FIG. 1, according to an exemplary embodiment of the present invention;

FIG. 5 is a perspective view of a curved display panel and an reinforcement member in an assembled state of the curved display device of FIG. 1, according to an exemplary embodiment of the present invention;

FIG. 6 is a plan view of the curved display panel and the reinforcement member of FIG. 5, according to an exemplary embodiment of the present invention;

FIG. 7 is a cross-sectional view taken along line I-I′ of FIG. 6, according to an exemplary embodiment of the present invention;

FIG. 8 is a cross-sectional view taken along line II-II′ of FIG. 6, according to an exemplary embodiment of the present invention;

FIG. 9 is a plan view illustrating an example of the reinforcement member of FIG. 1, according to an exemplary embodiment of the present invention;

FIG. 10 is a cross-sectional view illustrating an example of the reinforcement member of FIG. 1, corresponding to FIG. 7, according to an exemplary embodiment of the present invention;

FIG. 11 is a cross-sectional view illustrating an example of the reinforcement member of FIG. 1, corresponding to FIG. 8, according to an exemplary embodiment of the present invention;

FIG. 12 is an exploded perspective view of a curved display device according to an exemplary embodiment of the present invention;

FIG. 13 is a plan view illustrating pixels of the curved display device of FIG. 12, according to an exemplary embodiment of the present invention;

FIG. 14 is a plan view of a curved display panel and a reinforcement member of the curved display device of FIG. 12 in an assembled state, according to an exemplary embodiment of the present invention;

FIG. 15 is a cross-sectional view taken along line III-III′ of FIG. 14, according to an exemplary embodiment of the present invention;

FIG. 16 is a cross-sectional view taken along line IV-IV′ of FIG. 14, according to an exemplary embodiment of the present invention; and

FIGS. 17, 18, 19, 20 and 21 are views illustrating processes of a method for manufacturing a curved display device according to an exemplary embodiment of the present invention.

### DETAILED DESCRIPTION OF THE EMBODIMENTS

Exemplary embodiments of the present invention and methods of accomplishing the same will be described in detail with reference to the accompanying drawings. The present invention, however, may be embodied in many different forms and should not be construed as being limited to the exemplary embodiments set forth herein.

It will also be understood that when a layer is referred to as being “on” another layer or substrate, it can be directly on the other layer or substrate, or intervening layers may also be present. The same reference numbers may indicate the same components throughout the specification.

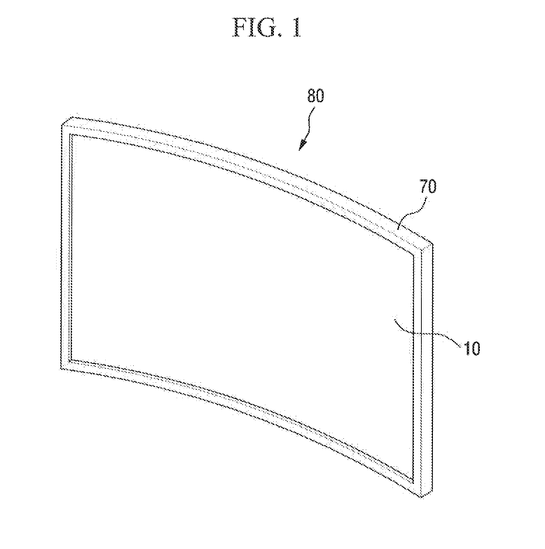

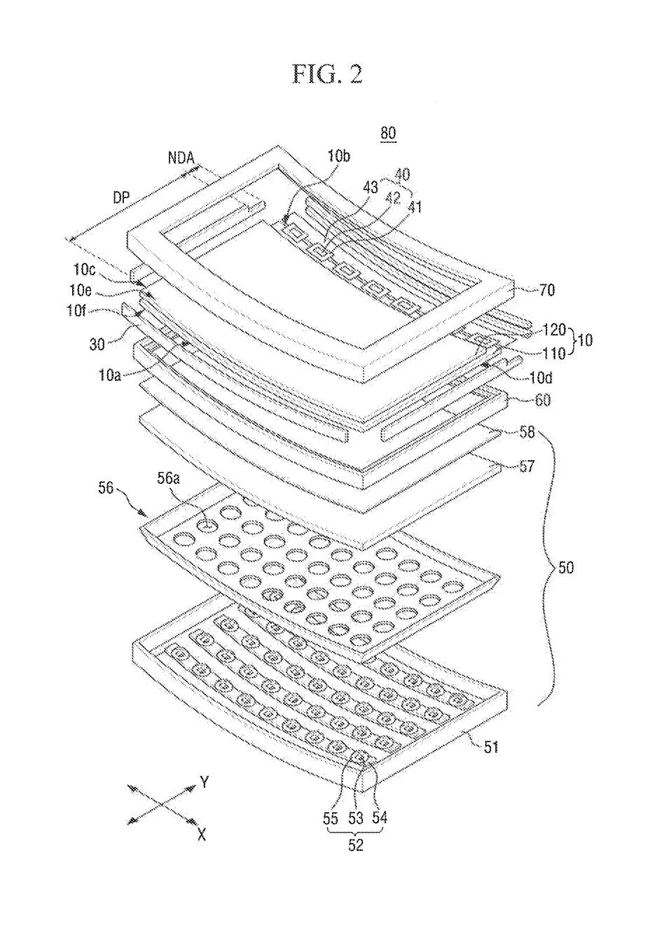

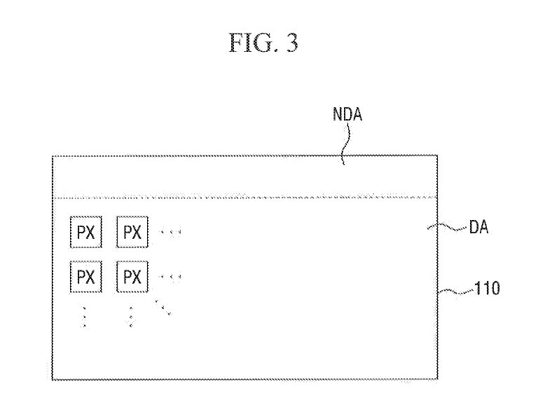

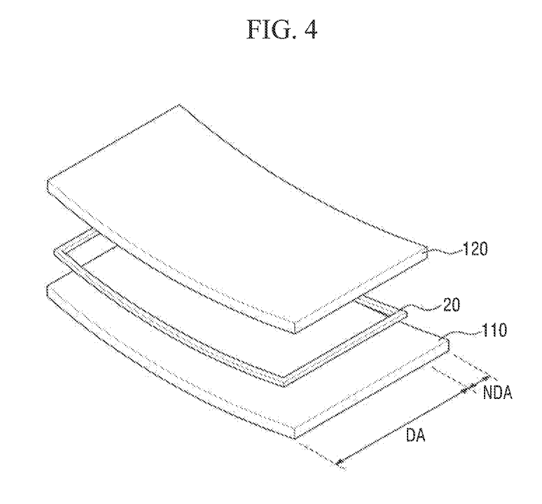

FIG. 1 is a perspective view of a curved display device in an assembled state according to an exemplary embodiment of the present invention. FIG. 2 is an exploded perspective view of the curve display device of FIG. 1, according to an exemplary embodiment of the present invention. FIG. 3 is a plan view illustrating pixels of the curved display device of FIG. 1, according to an exemplary embodiment of the present invention. FIG. 4 is a perspective view of a curved display panel and a sealing member in a separated state of the curved display device of FIG. 1, according to an exemplary embodiment of the present invention.

Referring to FIGS. 1 to 4, a curved display device 80 may have a curvature at least partly and may include a curved display panel 10, a sealing member 20, a reinforcement member 30, a driving portion 40, a backlight unit 50, a middle receptacle 60, and an upper receptacle 70.

The curved display panel 10 may have a shape that corresponds to the curvature of the curved display device 80. The curved display panel 10 may include a first side surface 10a including a curved side, a second side surface 10b including a curved side and be parallel to the first side surface 10a, a third side surface 10c, and a fourth side surface 10d. The third side surface 10c may connect the first side surface 10a and the second side surface 10b. The fourth side surface 10d may connect the first side surface 10a and the second side surface 10b. The fourth side surface 10d may be parallel to the third side surface 10c. The curved display panel 10 may include a first curved surface 10e and a second curved surface 10f, each of which connect the first to fourth side surfaces 10a, 10b, 10c, and 10d. The first and second curved surfaces 10e and 10f have curved surface shapes and are parallel to each other. The third side surface 10c and the fourth side surface 10d of the curved display panel 10 may not have curved sides. For example, the third side surface 10c and the fourth side surface 10d of the curved display panel 10 may include straight sides.

FIG. 2 illustrates that the first curved surface 10e and the second curved surface 10f extend in a first direction X and are curved about an axis in a second direction Y that crosses the first direction X, but exemplary embodiments of the present invention are not limited thereto. For example, the first curved surface 10e and the second curved surface 10f may be curved about an axis in the first direction X. In this case, the third side surface 10c and the fourth side surface 10d may have curved sides.

The curved display panel 10 may include a first substrate 110 and a second substrate 120 that face each other. A liquid crystal layer LCL (in FIG. 7) that includes liquid crystals LC (in FIG. 7) may be interposed between the first substrate 110 and the second substrate 120. A polarizing sheet may also be attached to outside of the first substrate 110 and to the outside of the second substrate 120.

As illustrated in FIG. 3, the first substrate 110 may include a display area DA that includes a plurality of pixels for displaying an image, and a non-display area NDA that is positioned on at least one side of the display area DA. The display area DA of the first substrate 110 may include a plurality of pixel electrodes, wirings for driving the pixel electrodes, and a plurality of thin film transistors.

The second substrate 120 may be combined with the first substrate 110 to face the first substrate 110. The second substrate 120 may have a size that is smaller than a size of the first substrate 110. The second substrate 120 may cover the display area DA of the first substrate 110 and may expose the non-display area NDA of the first substrate 110. On the non-display area NDA of the first substrate 110, the driving portion 140 (to be described later) may be connected.

A common electrode may be provided on the first substrate 110 or on the second substrate 120, and an electric field may be applied to the liquid crystal layer LCL (in FIG. 7). The plurality of thin film transistors that may be formed on the display area DA of the first substrate 110 and apply data voltages to the plurality of pixel electrodes in response to gate signals. If a common voltage is applied to the common electrode, the alignment of liquid crystals LC (in FIG. 7) of the liquid crystal layer LCL (in FIG. 7) may be changed. In accordance with the changed alignment of the liquid crystals LC (in FIG. 7), permeability of light that is provided from the backlight unit 50 may be adjusted to display an image. Further, color filters and black matrixes may be formed on the first substrate 110 or on the second substrate 120.

Each of the first substrate 110 and the second substrate 120 may include a first side surface, a second side surface, a third side surface, and a fourth side surface. The first substrate 110 may include a second curved surface which may correspond to the second curved surface 10f of the curved display panel 10. The second substrate 120 may include a first curved surface which may correspond to the first curved surface 10e of the curved display panel 10. The first side surface of the first substrate 110 may correspond to the first side surface 10a of the curved display panel 10. The second side surface of the first substrate 110 may correspond to the second side surface 10b of the curved display panel 10. The third side surface of the first substrate 110 may correspond to the third side surface 10c of the curved display panel 10. The fourth side surface of the first substrate 110 may correspond to the fourth side surface 10d of the curved display panel 10. The first side surface of the second substrate 120 may correspond to the first side surface 10a of the curved display panel 10. The second side surface of the second substrate 120 may correspond to the second side surface 10b of the curved display panel 10. The third side surface of the second substrate 120 may correspond to the third side surface 10c of the curved display panel 10. The fourth side surface of the second substrate 120 may correspond to the fourth side surface 10d of the curved display panel 10.

The sealing member 20 may be interposed between the first substrate 110 and the second substrate 120 to surround the display area DA of the first substrate 110. The sealing member 20 may combine the first substrate 110 and the second substrate 120 with each other. The sealing member 20 may contact opposite surfaces of the first substrate 110 and the second substrate 120. The sealing member 20 may include a sealing material, for example, photocurable resin or thermosetting resin.

The reinforcement member 30 may be arranged on an outside of the sealing member 20 and may be attached to at least one of the first to fourth side surfaces 10a to 10d of the curved display panel 10. The reinforcement member 30 may fill cracks that may occur on at least one of cut surfaces of the curved display panel 10 (e.g., at least one of the first to fourth side surfaces 10a to 10d of the curved display panel 10). The cut surfaces of the curved display panel 10 (e.g., the first to fourth side surfaces 10a to 10d of the curved display panel 10) may correspond to the first to fourth side surfaces of the first substrate 110 and to the first to fourth side surfaces of the second substrate 120. The cut surfaces of the curved display panel 10 may be formed by cutting a mother panel to a unit of a cell (e.g., one cell unit corresponds to one display device). The curved display panel 10 may be formed by performing a bending process with respect to the cut panel. Thus, the cracks may be prevented from propagating to the inside of the first substrate 110 or the second substrate 120 to reduce damage to the first substrate 110 or the second substrate 120. The reinforcement member 30 may include a reinforcement material, for example, it may include at least one material included in the sealing member 20 or a material that is different from the materials included in the sealing member 20. In the case where the reinforcement member 30 includes a material that is different from at least one material included in the sealing member 20, it may include, for example, frit. The reinforcement member 30 will be described later.

The driving portion 40 may be arranged on the non-display area NDA of the first substrate 110 and may apply a driving signal to the curved display panel 10. The driving portion 40 may include a flexible printed circuit board 41, a driving chip 42 mounted on the flexible printed circuit board 41, and a printed circuit board 43 connected to the flexible printed circuit board 41.

The printed circuit board 43 may provide the driving signal to the curved display panel 10 through the flexible printed circuit board 41. The driving chip 42 may include a built-in data driver that may apply a data voltage to the curved display panel 10. A gate driver that may provide a gate signal to the curved display panel 10 may be directly formed through a thin film process for forming a thin film on the curved display panel 10. Further, the driving chip 42 may be mounted in the form of a chip on glass (COG) on the non-display area NDA of the curved display panel 10.

The backlight unit 50 may have a shape that may correspond to the curvature of the curved display panel 10. The backlight unit 50 may provide light to the curved display panel 10, and may include a lower receptacle 51, a light source module 52, a reflective sheet 56, an optical plate 57, and an optical sheet 58.

The lower receptacle 51 may be formed to accommodate the light source module 52, the reflective sheet 56, the optical plate 57, and the optical sheet 58. The lower receptacle 51 may be a bottom chassis. The lower receptacle 51 may include a recessed portion in which the light source module 52 may be arranged.

The light source module 52 may include a plurality of light sources 53 that generate light which may be provided to the curved display panel 10. The light sources 53 may include, for example, one or a plurality of light emitting diodes (LEDs) that may generate light. The light source module 52 may include a printed circuit board 54 for light sources that may provide a power for driving the plurality of light sources 53. The light source module 52 may also include an optical lens 55 for diffusing light emitted from the plurality of light sources 53.

The reflective sheet 56 may reflect light, which is directed to a lower side thereof, toward an upper side thereof. The reflective sheet 56 may be integrally connected in a body. The reflective sheet 56 may include openings 56a, the number of which may be equal to the number of light sources 53.

The optical plate 57 and the optical sheet 58 are light modulation structures and may be arranged on an upper portion of the light source module 52 to modulate the light. In an exemplary embodiment of the present invention, the optical plate 57 may be a diffusion plate. The optical sheet 58 may include a prism sheet, a diffusion sheet, a micro lens sheet, a lenticular sheet, a phase difference compensation sheet, or a reflective polarizing sheet.

The middle receptacle 60 may have a shape that may correspond to the curvature of the curved display panel 10. The middle receptacle 60 may be arranged on an upper portion of the optical sheet 58, and may be a mold frame or a middle mold. The middle receptacle 60 may be fastened to the lower receptacle 51. In an exemplary embodiment of the present invention, the middle receptacle 60 may be fixed to the lower receptacle 51. The middle receptacle 60 may accommodate the curved display panel 10, the optical plate 57, and the optical sheet 58.

The upper receptacle 70 may have a shape that may correspond to the curvature of the curved display panel 10. The upper receptacle 70 may be arranged on the upper portion of the curved display panel 10, and may be a top chassis or a bezel. The upper receptacle 70 may include an open window, and may cover an edge of the curved display panel 70 to protect it. The upper receptacle 70 may be combined with the lower receptacle 51.

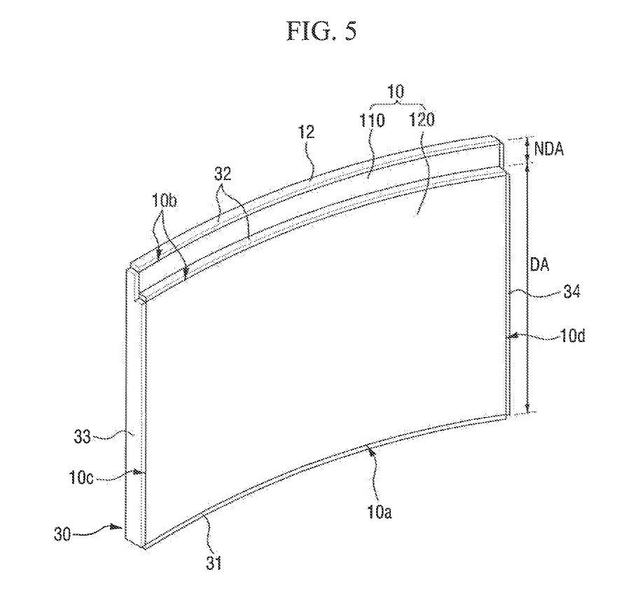

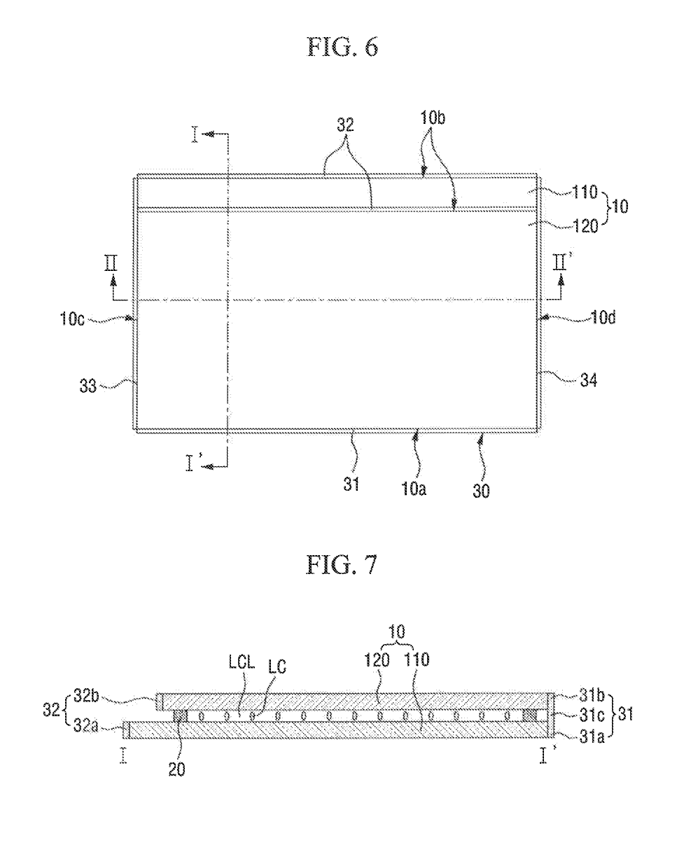

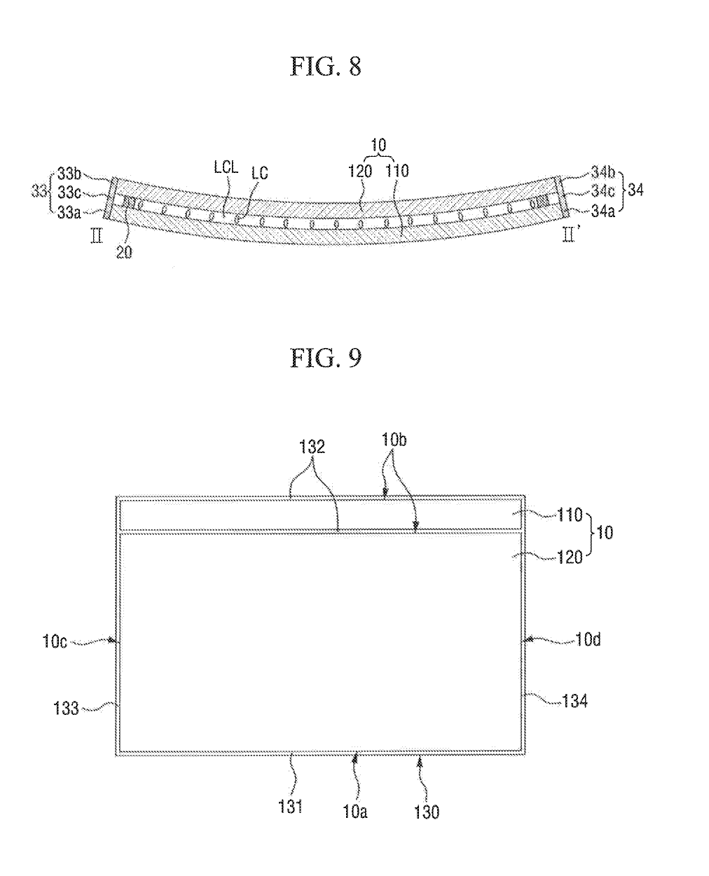

FIG. 5 is a perspective view of a curved display panel and a reinforcement member in an assembled state of the curved display device of FIG. 1, according to an exemplary embodiment of the present invention. FIG. 6 is a plan view of the curved display panel and the reinforcement member of FIG. 5, according to an exemplary embodiment of the present invention. FIG. 7 is a cross-sectional view taken along line I-I′ of FIG. 6, according to an exemplary embodiment of the present invention. FIG. 8 is a cross-sectional view taken along line II-II′ of FIG. 6, according to an exemplary embodiment of the present invention.

Referring to FIGS. 5 to 8, the reinforcement member 30 may include a first reinforcement member 31 arranged on the first side surface 10a of the curved display panel 10, a second reinforcement member 32 arranged on the second side surface 10b, a third reinforcement member 33 arranged on the third side surface 10c, and a fourth reinforcement member 34 arranged on the fourth side surface 10d.

The first reinforcement member 31 may include a curved side that may correspond to the first side surface 10a of the curved display panel 10. If cracks occur on the first side surface 10a of the curved display panel 10, for example, on the first side surface of the first substrate 110 or the first side surface of the second substrate 120, the first reinforcement member 31 may fill the cracks. Thus the cracks may be prevented from propagating from the first side surface of the first substrate 110 or the first side surface of the second substrate 120 to the inside of the first substrate 110 or the inside of the second substrate 120 to reduce damage to the first substrate 110 or to the second substrate 120. Damage to the first and second substrates 110 and 120, respectively, may include actual damage that may have occurred to the first and second substrates 110 and 120 (e.g., cracks from curving the first and second substrates 110 and 120), and potential damage that may occur to the first and second substrates 110 and 120 in the future (e.g., propagating cracks). The first side surface 10a of the curved display panel 10 may include a curved side of the curved display panel 10 and may be subjected to high stress resulting from curving the curved display panel 10. As the stress on at least one of the first, second, third and fourth side surfaces 10a, 10b, 10c, and 10d of the curved display panel 10 increases, the propagation rate of the cracks that may propagate to the inside of the first substrate 110 or the inside of the second substrate 120 may also increase. The first reinforcement member 31 may be arranged on the side surface 10a, which may have a high crack propagation rate among the side surfaces 10a to 10d of the curved display panel 10, to substantially reduce the propagation rate of the cracks that may occur on the curved display panel 10.

The first side surface of the first substrate 110 and the first side surface of the second substrate 120 may be arranged on the same plane. In this case, the first reinforcement member 31 may include a first portion 31a arranged on the first side surface of the first substrate 110, a second portion 31b arranged on the first side surface of the second substrate 120, and a third portion 31c connecting the first portion 31a and the second portion 31b to each other. The first portion 31a, the second portion 31b, and the third portion 31c may form one continuous structure.

The first portion 31a and the second portion 31b may substantially fill the cracks that may occur on the first side surface of the first substrate 110 or the first side surface of the second substrate 120. Thus the cracks may be prevented from propagating from the first side surface of the first substrate 110 to the inside of the first substrate 110 or from the first side surface of the second substrate 120 to the inside of the second substrate 120. The third portion 31c may be arranged on an outside of the sealing member 20 to intercept an inflow of moisture, or the like, from the outside to an inside of the sealing member 20.

The first portion 31a and the second portion 31b may be formed by dispersing (e.g., spreading) a reinforcement material on the first side surface of the first substrate 110 and on the first side surface of the second substrate 120 and then melting the spread reinforcement material by laser, or the like. The third portion 31c may be formed by a flow of the reinforcement material when the reinforcement material is melted.

The second reinforcement member 32 may be formed to include a curved side that may correspond to the second side surface 10b of the curved display panel 10. If cracks occur on the second side surface 10b of the curved display panel 10, for example, on the second side surface of the first substrate 110 or on the second side surface of the second substrate 120, the second reinforcement member 32 may fills the cracks. Thus, the cracks may be prevented from propagating from the second side surface of the first substrate 110 to the inside of the first substrate 110 or from the second side surface of the second substrate 120 to the inside of the second substrate 120.

The second side surface of the first substrate 110 and the second side surface of the second substrate 120 may be arranged on planes that are different from each other. In this case, the second reinforcement member 32 may include a first portion 32a arranged on the second side surface of the first substrate 110 and a second portion 32b arranged on the second side surface of the second substrate 120. In this case, the first portion 32a and the second portion 32b may be spaced apart from each other.

The first portion 32a and the second portion 32b may substantially fill the cracks that may occur on the second side surface of the first substrate 110 or on the second side surface of the second substrate 120. Thus the cracks may be prevented from propagating from the second side surface of the first substrate 110 to the inside of the first substrate 110 or from the second side surface of the second substrate 120 to the inside of the second substrate 120. Here, the second side surface 10b of the curved display panel 10 may include a curved side of the curved display panel 10 and may be subjected to high stress resulting from curving the curved display panel 10. The second reinforcement member 32 may be arranged on the side surface 10b, which may have high crack propagation rate among the side surfaces 10a to 10d of the curved display panel 10, to substantially reduce the propagation rate of the cracks that may occur on the curved display panel 10.

The first portion 32a and the second portion 32b may be formed by spreading a reinforcement material on the second side surface of the first substrate 110 and on the second side surface of the second substrate 120 and then melting the spread reinforcement material by laser, or the like.

If cracks occur on the third side surface 10c of the curved display panel 10, for example, on the third side surface of the first substrate 110 or on the third side surface of the second substrate 120, the third reinforcement member 33 may fill the cracks. Thus, the cracks may be prevented from propagating from the third side surface of the first substrate 110 to the inside of the first substrate 110 or from the third side surface of the second substrate 120 to the inside of the second substrate 120 to reduce damage to the first substrate 110 or to the second substrate 120. In an exemplary embodiment of the present invention, the third side surface 10c of the curved display panel 10 does not include a curved side Thus, the third side surface 10c of the curved display panel 10 does not have a stress resulting from a curved side. However, even if cracks occur on the third side surface 10c of the curved display panel 10, the crack propagation rate may be low. Accordingly, in some exemplary embodiments of the present invention, the third reinforcement member 33 may be omitted.

The third side surface of the first substrate 110 and the third side surface of the second substrate 120 may be arranged on the same plane. In this case, the third reinforcement member 33 may include a first portion 33a arranged on the third side surface of the first substrate 110, a second portion 33b arranged on the third side surface of the second substrate 120, and a third portion 33c connecting the first portion 33a and the second portion 33b to each other. The first portion 33a, the second portion 33b, and the third portion 33c may form one continuous structure. Since the roles of the first portion 33a, the second portion 33b, and the third portion 33c of the third reinforcement member 33 are substantially the same as the roles of the first portion 31a, the second portion 31b, and the third portion 31c of the first reinforcement member 31, a duplicate explanation thereof will be omitted for brevity.

If cracks occur on the fourth side surface 10d of the curved display panel 10, specifically, on the fourth side surface of the first substrate 110 or on the fourth side surface of the second substrate 120, the fourth reinforcement member 34 may fill the cracks. Thus the cracks may be prevented from propagating from the fourth side surface of the first substrate 110 to the inside of the first substrate 110 or from the fourth side surface of the second substrate 120 to the inside of the second substrate 120 to reduce damage to the first substrate 110 or to the second substrate 120. In an exemplary embodiment of the present invention, the fourth side surface 10d of the curved display panel 10 does not include a curved side. Thus, the fourth side surface 10d of the curved display panel 10 does not have a stress due to the curved side. However, even if cracks occur on the fourth side surface 10d of the curved display panel 10, the crack propagation rate may be low. Accordingly, in some exemplary embodiments of the present invention, the fourth reinforcement member 34 may be omitted.

The fourth side surface of the first substrate 110 and the fourth side surface of the second substrate 120 may be arranged on the same plane. In this case, the fourth reinforcement member 34 may include a first portion 34a arranged on the fourth side surface of the first substrate 110, a second portion 34b arranged on the fourth side surface of the second substrate 120, and a third portion 34c connecting the first portion 34a and the second portion 34b to each other. The first portion 34a, the second portion 34b, and the third portion 34c may form one continuous structure. Since the roles of the first portion 34a, the second portion 34b, and the third portion 34c of the fourth reinforcement member 34 are substantially the same as the roles of the first portion 31a, the second portion 31b, and the third portion 31c of the first reinforcement member 31, a duplicate explanation thereof will be omitted for brevity.

Next, various examples of the reinforcement member, according to exemplary embodiments of the present invention, will be described.

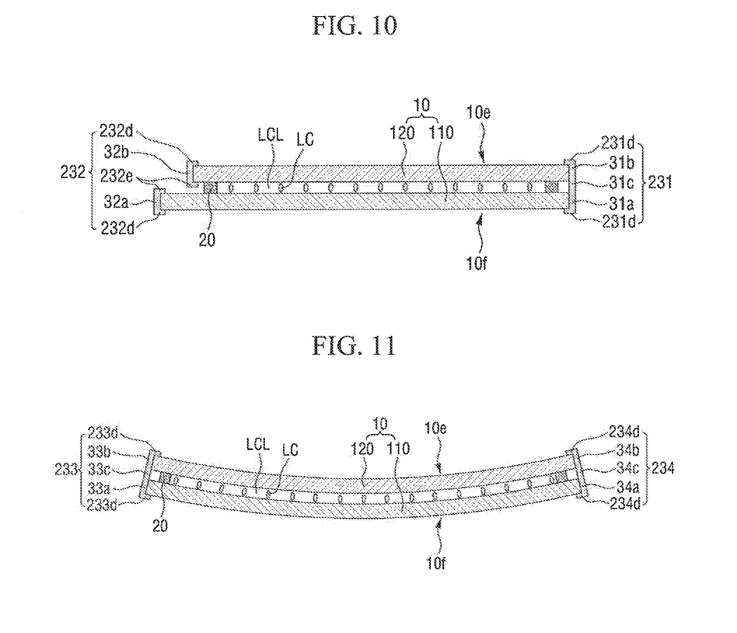

FIG. 9 is a plan view illustrating an example of the reinforcement member of FIG. 1 according to an exemplary embodiment of the present invention. FIG. 10 is a cross-sectional view illustrating an example of the reinforcement member of FIG. 1, corresponding to FIG. 7, according to an exemplary embodiment of the present invention. FIG. 11 is a cross-sectional view illustrating an example of the reinforcement member of FIG. 1, corresponding to FIG. 8, according to an exemplary embodiment of the present invention.

FIG. 9 illustrates that the reinforcement member 130 may includes one connected structure. For example, the reinforcement member 130 may be formed in a manner that a first reinforcement member 131 arranged on the first side surface 10a of the curved display panel 10, a second reinforcement member 132 arranged on the second side surface 10b of the curved display panel 10, a third reinforcement member 133 arranged on the third side surface 10c of the curved display panel 10, and a fourth reinforcement member 134 arranged on the fourth side surface 10d of the curved display panel 10 may be connected to form one continuous structure.

The reinforcement member 130 may reduce paths through which moisture, or the like, may be drawn to the inside of the curved display panel 10, and may increase the resistance of the curved display panel 10 against an external impact.

FIGS. 10 and 11 illustrate that a reinforcement member 230 may include a first reinforcement member 231 arranged on the first side surface 10a (in FIG. 6) of the curved display panel 10, a second reinforcement member 232 arranged on the second side surface 10b (in FIG. 6) of the curved display panel 10, a third reinforcement member 233 arranged on the third side surface 10c (in FIG. 6) of the curved display panel 10, and a fourth reinforcement member 234 arranged on the fourth side surface 10d (in FIG. 6) of the curved display panel 10. The first reinforcement member 231, the second reinforcement member 232, the third reinforcement member 233, and the fourth reinforcement member 233 include extension portions that are arranged at edges of the first curved surface 10e and the second curved surface 10f of the curved display panel 10.

For example, the first reinforcement member 231 may include fourth portions 231d extending from the first portion 31a and the second portion 31b to the edges of the second curved surface 10f and the first curved surface 10e of the curved display panel 10. The second reinforcement member 232 may include fourth portions 232d extending from the first portion 32a and the second portion 32b to the edges of the second curved surface 10f and the first curved surface 10e of the curved display panel 10. The second reinforcement member 232 may further include fifth portions 232e extending from the first portion 32a and the second portion 32b to edges of opposite surfaces of the first substrate 110 and the second substrate 120. The third reinforcement member 233 may include fourth portions 233d extending from the first portion 33a and the second portion 33b to the edges of the second curved surface 10f and the first curved surface 10e of the curved display panel 10. The fourth reinforcement member 234 may include fourth portions 234d extending from the first portion 34a and the second portion 34b to the edges of the second curved surface 10f and the first curved surface 10e of the curved display panel 10.

The reinforcement member 230 may increase the resistance of the curved display panel 10 against an external impact.

The curved display device 80, according to an exemplary embodiment of the present invention, includes the reinforcement member 30 which is arranged on the outside of the sealing member 20 and is attached to at least one of the first to fourth side surfaces 10a to 10d of the curved display panel 10. The reinforcement member 30 may fill the cracks that may occur on at least one of the cut surfaces of the curved display panel 10 (e.g., at least one of the first to fourth side surfaces 10a to 10d of the curved display panel 10). The cut surfaces of the curved display panel 10 (e.g., the first to fourth side surfaces 10a to 10d of the curved display panel 10) may correspond to the first to fourth side surfaces of the first substrate 110 and to the first to fourth side surfaces of the second substrate 120. The cut surfaces of the curved display panel 10 may be formed by cutting a mother panel to a unit of a cell (e.g., one cell unit corresponds to one display device). The curved display panel 10 may be formed by performing a bending process with respect to the cut panel. Thus the cracks may be prevented from propagating to the inside of the first substrate 110 or the second substrate 120 to reduce damage to the first substrate 110 or the second substrate 120.

Accordingly, the curved display panel 10 of the curved display device 80 may have an increased long-term reliability, according to an exemplary embodiment of the present invention.

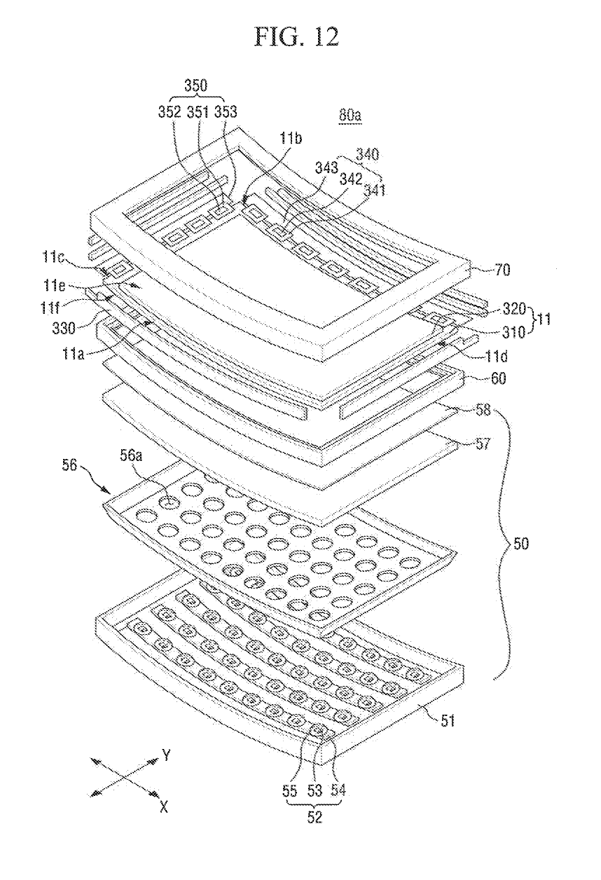

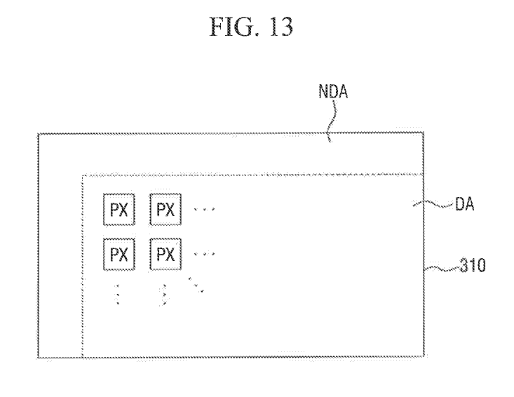

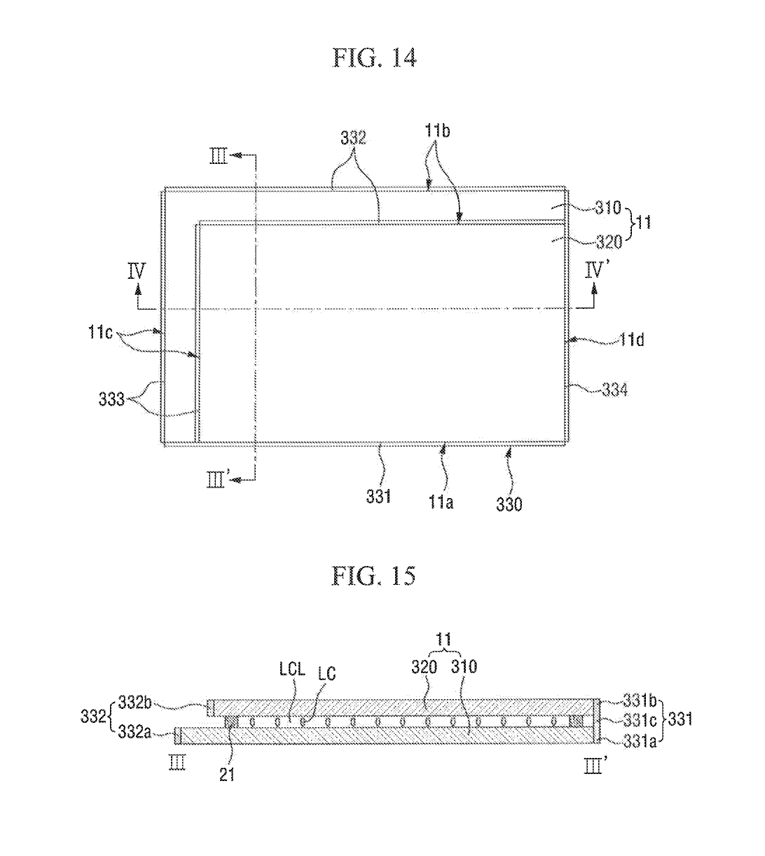

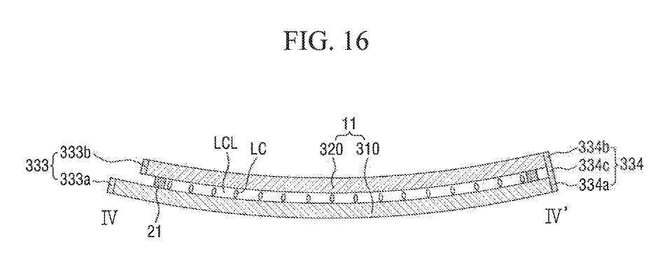

FIG. 12 is an exploded perspective view of a curved display device according to an exemplary embodiment of the present invention, and FIG. 13 is a plan view illustrating pixels of the curved display device of FIG. 12, according to an exemplary embodiment of the present invention. FIG. 14 is a plan view of a curved display panel and a reinforcement member of the curved display device of FIG. 12 in an assembled state, according to an exemplary embodiment of the present invention. FIG. 15 is a cross-sectional view taken along line III-III′ of FIG. 14, according to an exemplary embodiment of the present invention. FIG. 16 is a cross-sectional view taken along line IV-IV′ of FIG. 14, according to an exemplary embodiment of the present invention.

Referring to FIGS. 12 to 16, a curved display device 80a may have a curvature at least partly and may include a curved display panel 11, a sealing member 21, a reinforcement member 330, a first driving portion 340, a second driving portion 350, a backlight unit 50, a middle receptacle 60, and an upper receptacle 70.

The curved display panel 11 may have a shape that corresponds to the curvature of the curved display device 80a, and may include a first side surface 11a including a curved side, a second side surface 11b including a curved side and be parallel to the first side surface 11a, a third side surface 11c, and a fourth side surface 11d connecting the first side surface 11a and the second side surface 11b. The fourth side surface 11d may be parallel to the third side surface 11c. The curved display panel 11 may include a first curved surface 11e and a second curved surface 11f, the first and second curved surfaces 11e and 11f may be parallel to each other. Each of the first curved surface 11e and the second curved surface 11f may connect the first to fourth side surfaces 11a, 11b, 11c, and 11d.

FIG. 12 illustrates that the first curved surface 11e and the second curved surface 11f extend in the first direction X and are curved about an axis in the second direction Y that crosses the first direction X, but exemplary embodiments of the present invention are not limited thereto. For example, the first curved surface 11e and the second curved surface 11f may be curved about an axis in the first direction X. In this case, the third side surface 11c and the fourth side surface 11d may have curved sides.

The curved display panel 11 may include a first substrate 310 and a second substrate 320 that face each other. A liquid crystal layer LCL (in FIG. 15) that includes liquid crystals LC (in FIG. 15) may be interposed between the first substrate 310 and the second substrate 320. A polarizing sheet may also be attached to the outside of the first substrate 310 and to the outside of the second substrate 320.

The first substrate 310 is similar to the first substrate 110 of FIG. 2. However, as illustrated in FIG. 13, a difference between the first substrate 310 and the first substrate 110 is that the first substrate 310 may include a non-display area NDA on two side portions of the display area DA.

The second substrate 320 is similar to the second substrate 120 of FIG. 2. However, the second substrate 320 may have a size that is smaller than the size of the second substrate 120 to expose the non-display area NDA positioned on two side portions of the display area DA of the first substrate 310. The second substrate 320 may have a size that is smaller than a size of the first substrate 310.

Each of the first substrate 310 and the second substrate 320 may include a first side surface, a second side surface, a third side surface, a fourth side surface, a first curved surface, and a second curved surface. The first side surface of the first substrate 310 may correspond to the first side surface 11a of the curved display panel 11. The second side surface of the first substrate 310 may correspond to the second side surface 11b of the curved display panel 11. The third side surface of the first substrate 310 may correspond to the third side surface 11c of the curved display panel 11. The fourth side surface of the first substrate 310 may correspond to the fourth side surface 11d of the curved display panel 11. The first substrate 310 may include a second curved surface which may correspond to the second curved surface 11f of the curved display panel 11. The second substrate 320 may include a first curved surface which may correspond to the first curved surface 11e of the curved display panel 11. The first side surface of the second substrate 320 may correspond to the first side surface 11a of the curved display panel 11. The second side surface of the second substrate 320 may correspond to the second side surface 11b of the curved display panel 11. The third side surface of the second substrate 320 may correspond to the third side surface 11c of the curved display panel 11. The fourth side surface of the second substrate 320 may correspond to the fourth side surface 11d of the curved display panel 11.

The sealing member 21 may be similar to the sealing member 20 of FIG. 4. However, a circumferential length of the sealing member 21 may be smaller than a circumferential length of the sealing member 20.

The reinforcement member 330 may be arranged on an outside of the sealing member 21 and may be attached to at least one of the first to fourth side surfaces 11a to 11d of the curved display panel 11. The reinforcement member 330 may fill the cracks that may occur on at least one of cut surfaces of the curved display panel 11 (e.g., at least one of the first to fourth side surfaces 11a to 11d of the curved display panel 11). The cut surfaces of the curved display panel 11 (e.g., the first to fourth side surfaces 11a to 11d of the curved display panel 11) may correspond to the first to fourth side surfaces of the first substrate 310 and to the first to fourth side surfaces of the second substrate 320. The cut surfaces of the curved display panel 11 may be formed by cutting a mother panel in the unit of a cell (e.g., one cell unit corresponds to one display device). The curved display panel 11 may be formed by performing a bending process with respect to the cut panel. Thus, the cracks may be prevented from propagating to the inside of the first substrate 310 or the second substrate 320 to reduce damage to the first substrate 310 or the second substrate 320. The reinforcement member 330 may include a reinforcement material, for example, it may include at least one material included in the sealing member 21 or a material that is different from the materials included in the sealing member 21. In the case where the reinforcement member 330 is formed of a material that is different from at least one material included in the sealing member 21, it may include, for example, flit. The reinforcement member 330 will be described later.

The first driving portion 340 may be arranged on the non-display area NDA of the first substrate 310 that corresponds to the second side surface 11b of the curved display panel 11. The first driving portion 340 may apply a driving signal to the curved display panel 11. The first driving portion 340 may include a flexible printed circuit board 341, a driving chip 342 mounted on the flexible printed circuit board 341, and a printed circuit board 343 connected to the flexible printed circuit board 341. Since the first driving portion 340 is similar to the driving portion 40 of FIG. 2, a duplicate explanation thereof will be omitted for brevity.

The second driving portion 350 may be arranged on the non-display area NDA of the first substrate 310 that corresponds to the third side surface 11c of the curved display panel 11. The second driving portion 350 may apply a driving signal to the curved display panel 11. The second driving portion 350 may include a flexible printed circuit board 351, a driving chip 352 mounted on the flexible printed circuit board 351, and a printed circuit board 353 connected to the flexible printed circuit board 351. The driving chip 352 may have a built-in gate driver. The driving chip 352 may be mounted in the form of a COG on the curved display panel 11.

Since the backlight unit 50, the middle receptacle 60, and the upper receptacle 70 have been described in detail, a duplicate explanation thereof will be omitted for brevity.

The reinforcement member 330 will be described in detail.

The reinforcement member 330 may include a first reinforcement member 331 arranged on the first side surface 11a of the curved display panel 11, a second reinforcement member 332 arranged on the second side surface 11b of the curved display panel 11, a third reinforcement member 333 arranged on the third side surface 11c of the curved display panel 11, and a fourth reinforcement member 334 arranged on the fourth side surface 11d of the curved display panel 11.

The first reinforcement member 331 may include a first portion 331a arranged on the first side surface of the first substrate 310, a second portion 331b arranged on the first side surface of the second substrate 320, and a third portion 331c connecting the first portion 331a and the second portion 331b to each other. The third portion 331c may be similar to the first reinforcement member 31 of FIG. 7. However, the third portion 331c is not provided in a portion of the first side surface 11a of the curved display panel 11, which corresponds to the non-display area NDA of the first substrate 310.

The second reinforcement member 332 may include a first portion 332a arranged on the second side surface of the first substrate 310 and a second portion 332b arranged on the second side surface of the second substrate 320, and is similar to the second reinforcement member 32 of FIG. 7.

The third reinforcement member 333 is similar to the reinforcement member 33 of FIG. 8. However, since the third side surface of the first substrate 310 and the third side surface of the second substrate 320 are arranged on planes that may cross each other, the third reinforcement member 333 may include a first portion 333a arranged on the third side surface of the first substrate 310 and a second portion 333b arranged on the second side surface of the second substrate 320. In this case, the first portion 333a and the second portion 333b may be spaced apart from each other.

The fourth reinforcement member 334 may include a first portion 334a arranged on the fourth side surface of the first substrate 310, a second portion 334b arranged on the fourth side surface of the second substrate 320, and a third portion 334c connecting the first portion 331a and the second portion 331b to each other. The third portion 334c may be similar to the fourth reinforcement member 334 of FIG. 7.

As described above, the curved display device 80a according to an exemplary embodiment of the present invention may include a reinforcement member 330 which may be arranged on the outside of the sealing member 21. The reinforcement member 330 may be attached to at least one of the first to fourth side surfaces 11a to 11d of the curved display panel 11. Accordingly, the reinforcement member 330 may fills the cracks that may occur on at least one of the cut surfaces of the curved display panel 11 (e.g., at least one of the first to fourth side surfaces 11a to 11d of the curved display panel 11). The cut surfaces of the curved display panel 11 may be formed by cutting a mother panel to a unit of a cell (e.g., one cell unit corresponds to one display device). The curved display panel 11 may be formed by performing the bending process with respect to the cut panel. Thus the cracks may be prevented from propagating to the inside of the first substrate 310 or the second substrate 320 to reduce damage to the first substrate 310 or the second substrate 320.

Accordingly, the curved display panel 11 of the curved display device 80a may have increased long-term reliability according to an exemplary embodiment of the present invention.

A method for manufacturing a curved display device 80, according to an exemplary embodiment of the present invention will be described.

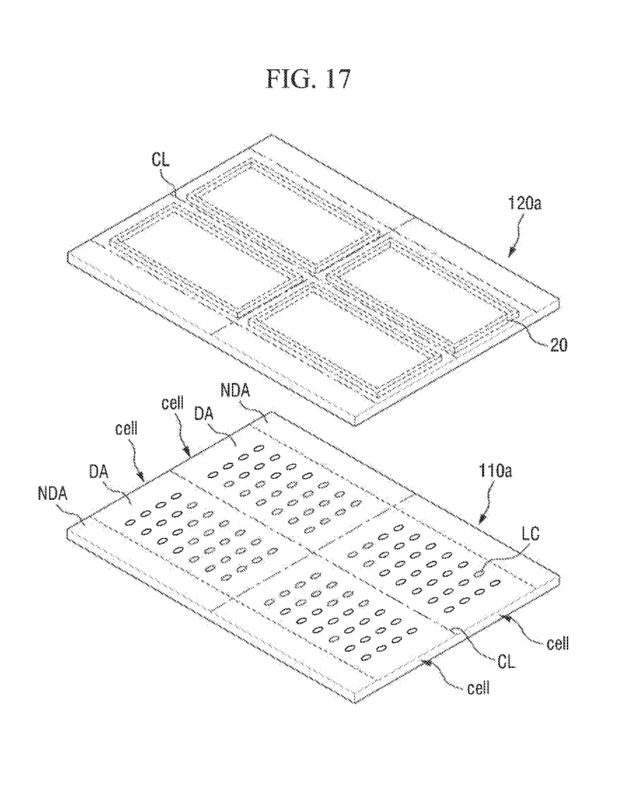

FIGS. 17, 18, 19, 20 and 21 are views illustrating processes of a method for manufacturing a curved display device according to an embodiment of the present invention.

Referring to FIG. 17, a first mother substrate 110a and a second mother substrate 120a may be prepared. The second mother substrate 120a may be arranged on an upper portion of the first mother substrate 110a.

On the first mother substrate 110a, a plurality of cells that include a display area DA for displaying an image and a non-display area NDA may be defined. Elements for displaying an image may be provided in each of the cells. For example, the elements may include a plurality of pixel electrodes, wirings for driving the pixel electrodes, and a plurality of thin film transistors. Further, liquid crystals LC may be provided on the display area DA of each of the cells.

On the second mother substrate 120a that faces the first mother substrate 110a, a sealing member 20 may be dispersed (e.g., spread) on an area that corresponds to an area that surrounds the liquid crystals LC of each of the cells of the first mother substrate 110a. Elements for displaying an image may also be provided on the second mother substrate 120a. For example, the elements may include a common electrode, color filters, and black matrixes. The common electrode, the color filters, and the black matrixes may be formed on the first mother substrate 120a.

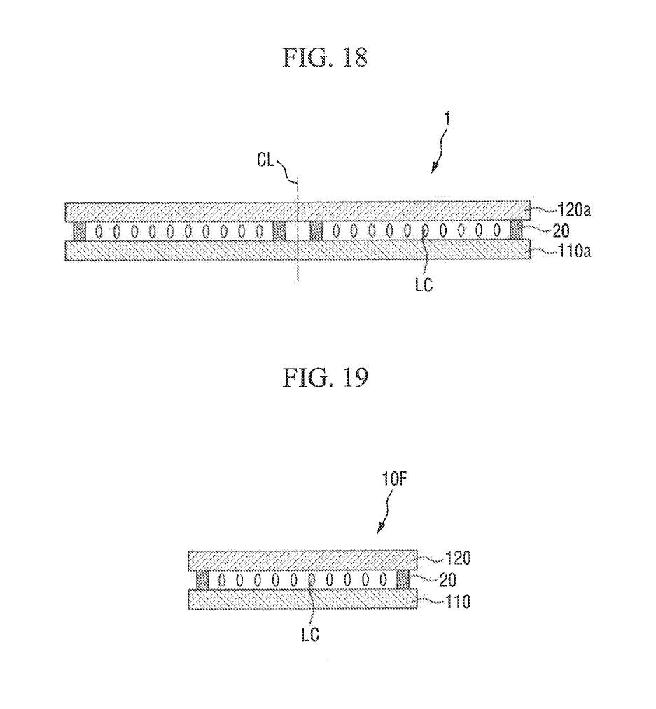

In FIG. 17, the reference “CL” denotes a cutting line CL, and may correspond to a portion of the first and second mother substrates 110a and 120a with which a cutting member may contact to cut the mother panel 1 (in FIG. 18). The mother panel 1 may include the first mother substrate 110a (which may include the plurality of cells, the plurality of display areas DA and the plurality of non-display areas NDA, the plurality of elements for displaying an image, the plurality of liquid crystals LC, and the plurality of cutting lines CL), and the second mother substrate 120a (which may include the plurality of sealing members 20, the plurality of elements for displaying an image and the plurality of cutting lines CL). The mother panel 1 may be cut to a unit of a cell, separating the plurality of cells from one another.

Referring to FIG. 18, the first mother substrate 110a and the second mother substrate 120a may be bonded through the sealant 20 to form the mother panel 1.

The sealant 20 may be cured by ultraviolet (UV) irradiation after the sealant 20 contacts the first mother substrate 110a. When the sealant 20 contacts the first mother substrate 110a, the liquid crystals LC may be interposed between the first mother substrate 110a and the second mother substrate 120a.

Referring to FIG. 19, by cutting the mother panel 1 (in FIG. 18) to the unit of a cell, a display panel 10F may be formed. In the display panel 10F, liquid crystals LC may be interposed between the first substrate 110 and the second substrate 120. Here, the cutting process may be performed using a cutting member such as a scribing wheel. The display panel 10F that may be formed by the cutting process may be in a flat state.

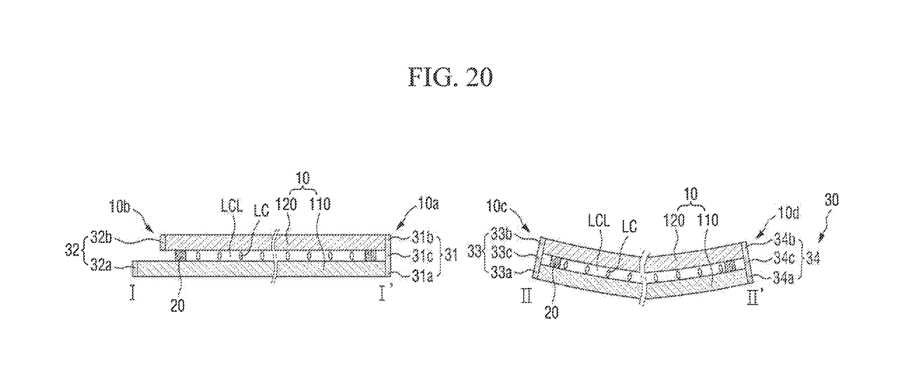

Referring to FIG. 20, a curved display panel 10 may be formed by performing of a bending process with respect to the display panel 10F, (e.g., bending the display panel 10F). The reinforcement member 30 may be formed on side surfaces 10a to 10d, (e.g., the cut surfaces), of the curved display panel 10. FIG. 20 illustrates cross-sectional portions taken along lines I-I′ and II-II′ of FIG. 6. The reinforcement member 30 may be formed by dispersing, (e.g., spreading) a reinforcement material on the side surfaces 10a to 10d of the curved display panel 10 and melting the spread reinforcement material by a laser, or the like.

The reinforcement member 30 may include a first reinforcement member 31 arranged on the first side surface 10a of the curved display panel 10, a second reinforcement member 32 arranged on the second side surface 10b of the curved display panel 10, a third reinforcement member 33 arranged on the third side surface 10c of the curved display panel 10, and a fourth reinforcement member 34 arranged on the fourth side surface 10d of the curved display panel 10. Since the detailed configuration of the reinforcement member 30 has been described in detail, a duplicate explanation thereof will be omitted for brevity. FIG. 20 illustrates cross-sectional portions taken along lines I-I′ and II-II′ of FIG. 6.

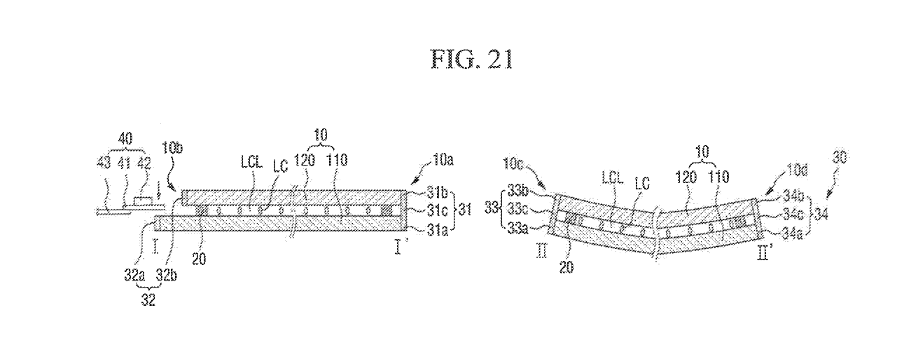

Referring to FIG. 21, the driving portion 40 may be connected to the non-display area NDA of the curved display panel 10. The connection of the driving portion 40 may be performed using an anisotropic conductive film. FIG. 21 illustrates cross-sectional portions taken along lines I-I′ and II-II′ of FIG. 6.

The curved display panel 10 may be combined by fastening together the curved display panel 10, the backlight unit 50, the middle receptacle 60, and the upper receptacle 70. Further, a polarizing sheet may be attached to the outer surfaces of the first substrate 110 and the second substrate 120 of the curved display panel 10. The attaching of the polarizing sheet may be performed before or after forming the reinforcement member 30.

A curved display device, according to an exemplary embodiment of the present invention, includes a reinforcement member arranged on an outside of a sealing member and attached to a side surface of a curved display panel of the curved display device to fill cracks that may occur on cut surfaces of the curved display panel. The curved display panel may be formed by cutting a mother panel in the unit of a cell and performing a bending process with respect to the cut panel. Thus, the cracks may be prevented from propagating to the inside of a first substrate of the curved display panel or to the inside of a second substrate of the curved display panel to reduce damage to the first substrate of the curved display panel or to the second substrate of the curved display panel. Accordingly, the curved display panel of the curved display device may have an increased long-term reliability, according to an exemplary embodiment of the present invention.

In concluding the detailed description, those skilled in the art will appreciate that many variations and modifications can be made to the exemplary embodiments of the present invention without departing from the scope of the present invention as defined in the claims.

What is claimed is:

1. A curved display device comprising:
a curved display panel including a first substrate and a second substrate facing the first substrate, wherein the first substrate includes a display area for displaying an image and a non-display area;
a sealing member interposed between the first substrate and the second substrate, wherein the sealing member surrounds the display area; and
a reinforcement member arranged on an outside of the sealing member,
wherein the curved display panel includes a first side surface including a curved side, a second side surface including a curved side and facing the first side surface, a third side surface, and a fourth side surface, wherein the third side surface connects the first side surface and the second side surface, and the fourth side surface connects the first side surface and the second side surface,
wherein the third side surface and the fourth side surface face each other, and
wherein the reinforcement member is attached to at least one of the first side surface and the second side surface.

2. The curved display device of claim 1, wherein the reinforcement member includes a curved side.

3. The curved display device of claim 1, wherein a first side surface of the first substrate that corresponds to the first side surface of the curved display panel is arranged on the same plane as a first side surface of the second substrate that corresponds to the first side surface of the curved display panel, and
the reinforcement member comprises a first reinforcement member, the first reinforcement member including a first portion arranged on the first side surface of the first substrate, a second portion arranged on the first side surface of the second substrate, and a third portion connecting the first portion and the second portion to each other.

4. The curved display device of claim 3, wherein the first portion, the second portion, and the third portion of the first reinforcement member form a continuous structure.

5. The curved display device of claim 3, wherein a second side surface of the first substrate that corresponds to the second side surface of the curved display panel and a second side surface of the second substrate that corresponds to the second side surface of the curved display panel are arranged on planes that are different from each other, and
the reinforcement member further comprises a second reinforcement member, the second reinforcement member including a first portion arranged on the second side surface of the first substrate and a second portion arranged on the second side surface of the second substrate.

6. The curved display device of claim 5, wherein the first portion and the second portion of the second reinforcement member are spaced apart from each other.

7. The curved display device of claim 5, wherein the reinforcement member is attached to at least one of the third side surface and the fourth side surface.

8. The curved display device of claim 5, wherein a third side surface of the first substrate that corresponds to the third side surface of the curved display panel is arranged on the same plane as a third side surface of the second substrate that corresponds to the third side surface of the curved display panel, and
the reinforcement member further comprises a third reinforcement member, the third reinforcement member including a first portion arranged on the third side surface of the first substrate, a second portion arranged on the third side surface of the second substrate, and a third portion connecting the first portion and the second portion to each other.

9. The curved display device of claim 8, wherein a fourth side surface of the first substrate that corresponds to the fourth side surface of the curved display panel is arranged on the same plane as a fourth side surface of the second substrate that corresponds to the fourth side surface of the curved display panel, and
the reinforcement member further comprises a fourth reinforcement member, the fourth reinforcement member including a first portion arranged on the fourth side surface of the first substrate, a second portion arranged on the fourth side surface of the second substrate, and a third portion connecting the first portion and the second portion to each other.

10. The curved display device of claim 1, wherein the reinforcement member has a connected structure.

11. The curved display device of claim 1, wherein the curved display panel includes a first curved surface and a second curved surface,
wherein the first and second curved surfaces connect the first side surface, the second side surface, the third side surface and the fourth side surface,
wherein the first and second curved surfaces are parallel to each other,
wherein the reinforcement member includes an extension portion,
and wherein the extension portion extends from at least one of the first side surface and the second side surface to edges of the first curved surface and the second curved surface.

12. The curved display device of claim 1, wherein the reinforcement member comprises the same material as the sealing member or a material that is different from a material of the sealing member.

13. The curved display device of claim 1, wherein the reinforcement member comprises frit.

14. The curved display device of claim 1, wherein the reinforcement member fills at least one crack on at least one of the first side surface and the second side surface of the curved display panel.

15. A curved display device comprising:
a curved display panel including a first substrate and a second substrate facing the first substrate, wherein the first substrate includes a display area for displaying an image and a non-display area;
a sealing member interposed between the first substrate and the second substrate, wherein the sealing member surrounds the display area; and
a reinforcement member arranged on an outside of the sealing member,
wherein the reinforcement member includes a first portion arranged on a first side surface of the first substrate,
a second portion arranged on a first side surface of the second substrate, wherein the first side surface of the second substrate corresponds to the first side surface of the first substrate; and
a third portion connecting the first portion and the second portion to each other.

16. The curved display device of claim 15, wherein the first portion, the second portion, and the third portion form a continuous structure.

17. The curved display device of claim 15, wherein the first side surface of the first substrate and the first side surface of the second substrate are arranged on the same plane.

18. The curved display device of claim 15, wherein the first side surface of the first substrate and the first side surface of the second substrate include curved sides or straight sides.

19. The curved display device of claim 15, wherein the reinforcement member comprises the same material as the sealing member or a material that is different from a material of the sealing member.

20. The curved display device of claim 15, wherein the reinforcement member comprises frit.
